(19) United States
(12) Patent Application Publication
(10) Pub. No.: US 2026/0331206 A1
(43) Pub. Date: Oct. 22, 2026

(54) PREDICTION AND SCHEDULING OF TESTING WHEN A MEMORY CELL IS IDLE

(71) Applicant: Microchip Technology Inc., Chandler, AZ (US)

(72) Inventors: Steve Nagel, Chandler, AZ (US); Bomy Chen, Newark, CA (US)

(73) Assignee: Microchip Technology Inc., Chandler, AZ (US)

(21) Appl. No.: 19/269,196

(22) Filed: Jul. 15, 2025

Related U.S. Application Data
(60) Provisional application No. 63/789,462, filed on Apr. 16, 2025.

(51) Int. Cl. G11C 29/46

(52) U.S. Cl. CPC G11C 29/46

(57) ABSTRACT

A system and method for predicting when a memory cell is idle and scheduling testing of the memory cell during an idle period are disclosed. The method may include identifying a predicted time when a memory cell is idle. The method may also include scheduling a test of the memory cell at a schedule time during the predicted time. The method may additionally include performing the test of the memory cell at the scheduled time. The method may include calculating a health score for the memory cell based on the test. The method may further include diagnosing the memory cell based on the health score.

### PRIORITY

This application claims priority to U.S. Provisional Patent Application No. 63/789,462 filed Apr. 16, 2025, the contents of which are hereby incorporated in their entirety.

### TECHNICAL FIELD

The present disclosure relates to monitoring the health of non-volatile memory, and in particular, to a system and method for predicting when a memory cell is idle and scheduling testing of the memory cell during an idle period.

### BACKGROUND

Non-volatile memory (NVM) refers to computer memory that can retain stored information even when not powered. There are several different types of NVM, including, but not limited to, Flash memory (e.g., SuperFlash, SONOS), magnetoresistive random access memory (RAM) (MRAM), resistive RAM (RRAM or ReRAM), ferroelectric RAM (FeRAM or FRAM), or phase-change memory (PCM or PCRAM). The semiconductor industry is increasingly using MRAM, RRAM, FRAM, and PCRAM, which may be used on nodes below 28 nanometers, provide faster support for over the air (OTA) updates, and allow more reuse (e.g., logic and analog models may be the same whether embedded NVM (eNVM) or non-embedded NVM). However, these types of NVM do not have a proven reliability track record.

Testing NVM is a process for ensuring data integrity, reliability, and endurance. The testing involves multiple stages and techniques. Functional tests verify the basic read, write, and erase operations, often using data patterns (like checkerboards or pseudo-random sequences) to detect failures or sensitivities between memory cells. NVM undergoes data retention testing, where data is written, power is removed, and then read back after a specified period to ensure information has not degraded. Endurance testing subjects memory cells to repeated program/erase cycles to confirm they meet the specified lifetime limits before failure. Performance characteristics like read and write speeds are measured against specifications and error correction code (ECC) mechanisms are validated for their ability to detect and correct errors.

### SUMMARY OF THE INVENTION

Aspects provide systems and methods for predicting when a memory cell is idle and scheduling testing of the memory cell during an idle period. Examples of the present disclosure may include an apparatus. The apparatus may include a memory cell interface communicatively coupled to a memory cell. The apparatus may also include a control circuit communicatively coupled to the memory cell interface. The control circuit may be to identify a predicted time when the memory cell is idle. The control circuit may also be to schedule a test of the memory cell at a schedule time during the predicted time. The control circuit may additionally be to perform the test of the memory cell at the scheduled time. The control circuit may be to calculate a health score for the memory cell based on the test. The control circuit may further be to diagnose the memory cell based on the health score.

In combination with any of the above examples, the control circuit may be to determine that the health score for the memory cell is marginal. The control circuit may also be to increase a testing frequency of the memory cell.

In combination with any of the above examples, the control circuit may be to determine that the health score for the memory cell is failed. The control circuit may also be to rewrite the memory cell.

In combination with any of the above examples, the control circuit may be to determine that the health score for the memory cell is failed. The control circuit may also be to trigger a failure alert indicating the memory cell has failed.

In combination with any of the above examples, the control circuit may be to determine that the health score for the memory cell is failed. The control circuit may also be to flag the memory cell as unusable.

In combination with any of the above examples, determining whether the memory cell is idle may include learning an operational schedule of the memory cell.

In combination with any of the above examples, the apparatus may include a second memory interface communicatively coupled to a second memory and the control circuit. Testing the memory cell may include comparing a content of the memory cell to a content of the second memory.

Alone or in combination with any of the above examples, examples of the present disclosure may include a method. The method may include identifying a predicted time when a memory cell is idle. The method may also include scheduling a test of the memory cell at a schedule time during the predicted time. The method may additionally include performing the test of the memory cell at the scheduled time. The method may include calculating a health score for the memory cell based on the test. The method may further include diagnosing the memory cell based on the health score.

In combination with any of the above examples, the method may include determining that the health score for the memory cell is marginal. The method may also include increasing a testing frequency of the memory cell.

In combination with any of the above examples, the method may include determining that the health score for the memory cell is failed. The method may also include rewriting the memory cell.

In combination with any of the above examples, the method may include determining that the health score for the memory cell is failed. The method may also include triggering a failure alert indicating the memory cell has failed.

In combination with any of the above examples, the method may include determining that the health score for the memory cell is failed. The method may also include flagging the memory cell as unusable.

In combination with any of the above examples, determining whether the memory cell is idle may include learning an operational schedule of the memory cell.

In combination with any of the above examples, testing the memory cell may include comparing a content of the memory cell to a content of a second memory.

Alone or in combination with any of the above examples, examples of the present disclosure may include a system. The system may include a memory cell. The system may also include a control circuit communicatively coupled to the memory cell. The control circuit may be to identify a predicted time when the memory cell is idle. The control circuit may also be to schedule a test of the memory cell at a schedule time during the predicted time. The control circuit may additionally be to perform the test of the memory cell at the scheduled time. The control circuit may be to calculate a health score for the memory cell based on the test. The control circuit may further be to diagnose the memory cell based on the health score.

In combination with any of the above examples, the control circuit may be to determine that the health score for the memory cell is marginal. The control circuit may also be to increase a testing frequency of the memory cell.

In combination with any of the above examples, the control circuit may be to determine that the health score for the memory cell is failed. The control circuit may also be to rewrite the memory cell.

In combination with any of the above examples, the control circuit may be to determine that the health score for the memory cell is failed. The control circuit may also be to trigger a failure alert indicating the memory cell has failed.

In combination with any of the above examples, the control circuit may be to determine that the health score for the memory cell is failed. The control circuit may also be to flag the memory cell as unusable.

In combination with any of the above examples, determining whether the memory cell is idle may include learning an operational schedule of the memory cell.

### BRIEF DESCRIPTION OF THE DRAWINGS

The figures illustrate examples of systems and methods for predicting when a memory cell is idle and scheduling testing of the memory cell during an idle period.

FIG. 1 illustrates a system for predicting when a memory cell is idle and scheduling testing of the memory cell during an idle period, according to examples of the present disclosure;

FIG. 2 illustrates a method for predicting when a memory cell is idle and scheduling testing of the memory cell during an idle period, according to examples of the present disclosure; and

FIG. 3 illustrates a more detailed method for predicting when a memory cell is idle and scheduling testing of the memory cell during an idle period, according to examples of the present disclosure.

The reference number for any illustrated element that appears in multiple different figures has the same meaning across the multiple figures, and the mention or discussion herein of any illustrated element in the context of any particular figure also applies to each other figure, if any, in which that same illustrated element is shown.

### DESCRIPTION

According to an aspect of the invention, a system and method for predicting when a memory cell is idle and scheduling testing of the memory cell during an idle period are provided. The disclosed system and method may monitor the health of non-volatile (NVM) incorporated into a device. The disclosed system and method may predict when an NVM memory cell will be idle, test the memory cell during a predicted idle time, and provide a health check score for the memory cell. For example, the device may be an automobile. The disclosed system and methods may learn the operational schedule of the automobile (e.g., when the automobile is parked) and perform testing during periods when the automobile is not in use to support predictive maintenance of the memory cells in the NVM. For example, as a result of the health monitoring, an early warning may be provided to replace a component prior to the component malfunctioning.

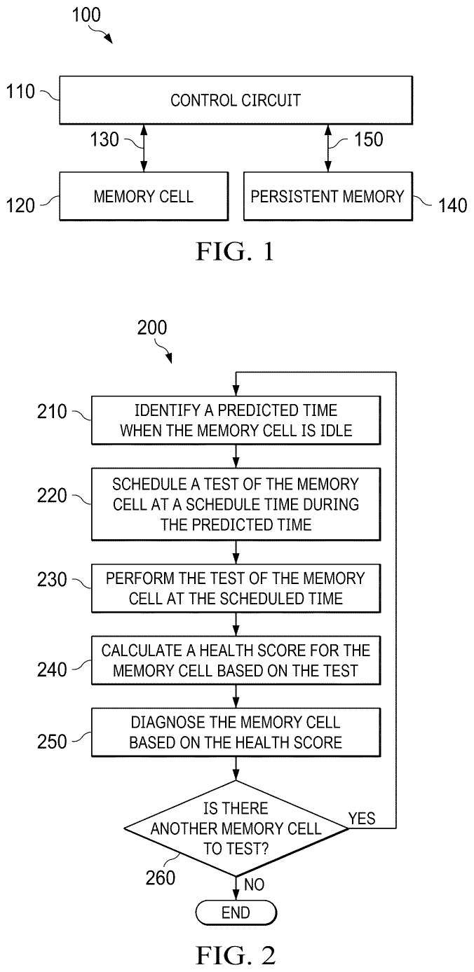

FIG. 1 illustrates a system for predicting when a memory cell is idle and scheduling testing of the memory cell during an idle period, according to examples of the present disclosure. System 100 may include control circuit 110, memory cell 120 communicatively coupled to control circuit 110 via memory cell interface 130, and persistent memory 140 communicatively coupled to control circuit 110 via persistent memory interface 150.

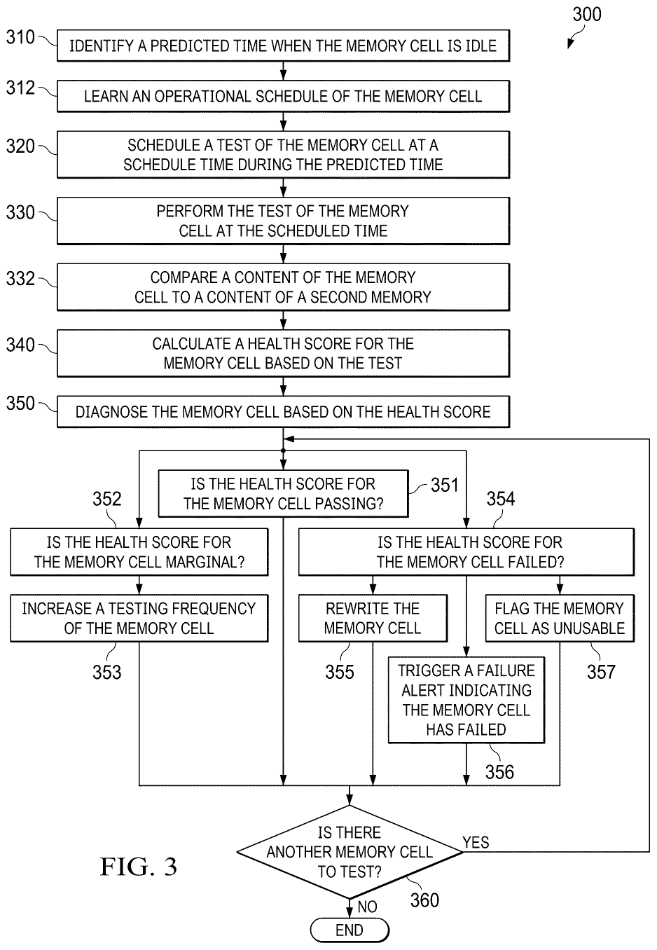

Control circuit 110 may monitor the operational schedule of the device in which system 100 is incorporated. The device may be any suitable device, including, but not limited to, devices in the automotive, industrial, robotic, or drone industries. Control circuit 110 may identify periods of time when the device is in use and periods of time when the device is idle. From this information, control circuit 110 may predict when the device may be idle and perform tests of memory cell 120 during the predicted idle time. Control circuit 110 may use the results of the testing to calculate a health score for memory cell 120 and diagnose memory cell 120 based on the health score. The functions of control circuit 110 are described in more detail with respect to FIGS. 2 and 3, below.

Control circuit 110 may be implemented by instructions for execution by a processor, analog circuitry, digital circuitry, control logic, digital logic circuits programmed through hardware description language, application specific integrated circuits (ASIC), field programmable gate arrays (FPGA), programmable logic devices (PLD), or any suitable combination thereof, whether in a unitary device or spread over several devices. Control circuit 110 may be implemented by instructions for execution by a processor through, for example, a function, application programming interface (API) call, script, program, compiled code, interpreted code, binary, executable, executable file, firmware, object file, container, assembly code, or object. For example, control circuit 110 may be implemented by instructions stored in a non-transitory medium such as a memory that, when loaded and executed by a processor such as a central processing unit (CPU) (or any other suitable process), cause the functionality of control circuit 110 herein.

Memory cell 120 may be used to store software, firmware, calibration data, configuration settings, or any other suitable information for controlling the operation of the device in which system 100 is incorporated. System 100 may include more than one memory cell 120. A failure of one or more memory cells 120 may cause issues to arise in the device, ranging in severity from a minor inconvenience to a serious malfunction. For example, the device may lose stored settings, display incorrect alert lights, crash, fail to boot, or lose functionality. Therefore, control circuit 110 may periodically test memory cell 120 to identify failing or failed memory cells 120 to alert an operator of the device before the operator experiences any of the symptoms of a failure of memory cell 120, as described in more detail with respect to FIGS. 2 and 3.

Memory cell 120 may be any suitable type of non-volatile memory, including but not limited to, read-only memory (ROM), random access memory (RAM) (e.g., static RAM (SRAM), dynamic RAM (DRAM), magnetoresistive RAM (MRAM), resistive RAM (RRAM or ReRAM), ferroelectric RAM (FeRAM or FRAM)), electrically erasable programmable read-only memory (EEPROM), a Personal Computer Memory Card International Association (PCMCIA) card, flash memory, magnetic storage, opto-magnetic storage, hardware registers, or phase-change memory (PCM or PCRAM), or any suitable selection or array of non-volatile memory.

Memory cell interface 130 may communicatively couple control circuit 110 and memory cell 120 to enable control circuit 110 to exchange information with memory cell 120. For example, memory cell interface 130 may allow control circuit 110 to communicatively couple to a bus to which memory cell 120 is also communicatively coupled.

Persistent memory 140 may be used to store software, firmware, calibration data, configuration settings, or any other suitable information for controlling the operation of the device in which system 100 is incorporated. Persistent memory 140 may be used to store a copy of information stored on memory cells 120. The copy of information stored on persistent memory 140 may be compared to the information stored on memory cells 120 during the process of testing of memory cell 120, as described in more detail with respect to FIG. and 3.

Persistent memory 140 may be any suitable type of non-volatile persistent memory, including but not limited to, multimedia card (MMC) or solid state drive (SSD), or any suitable selection or array of non-volatile memory.

Persistent memory interface 150 may communicatively couple control circuit 110 and persistent memory 140 to enable control circuit 110 to exchange information with persistent memory 140. For example, persistent memory interface 150 may allow control circuit 110 to communicatively couple to a bus to which persistent memory 140 is also communicatively coupled.

FIG. 2 illustrates a method for predicting when a memory cell is idle and scheduling testing of the memory cell during an idle period, according to examples of the present disclosure. Method 200 may be implemented using a control circuit such as control circuit 110 shown in FIG. 1 communicatively coupled to a memory cell, such as memory cell 120 shown in FIG. 1, designed to perform the functions disclosed herein, in combination with a processor, or any other system operable to implement method 200. Although examples have been described above, other variations and examples may be made from this disclosure without departing from the spirit and scope of these disclosed examples.

Method 200 may begin at block 210 where the control circuit may identify a predicted time when the memory cell may be idle. The memory cell may be incorporated into a device, such as but not limited to, devices in the automotive, industrial, robotic, or drone industries. The device may operate at some times and may have periods of time when the device is idle. For example, an automobile may be active while a driver is commuting to and from work, but may be idle while the driver is at work and while the driver is at home. The control circuit may periodically check the device to determine if it is idle or in operation. The control circuit may check the device on any suitable basis. For example, the control circuit may check the device on a schedule programmed in the control circuit or the operator of the device may specify how often the control circuit is to perform the check.

At block 220, the control circuit may schedule a test of the memory cell at a schedule time during the predicted time. For example, where the control circuit determines that the device is idle from 9:00 a.m. to 5:00 p.m. and from 6:00 p.m. to 8:00 a.m., the control circuit may schedule the test of the memory cell during that time. In some examples, the operator of the device may schedule the test. For example, the operator of the device may instruct the control circuit that the device is idle and control circuit may proceed to block 230 to test the memory cell. In other example, the control circuit may prompt the operator to confirm that the device is idle and that the control circuit may proceed to block 230.

At block 230, the control circuit may perform the test of the memory cell at the scheduled time. The test may be any suitable test, such as a memory margin test. A memory margin test may assess the robustness and reliability of the NVM and may determine how much “margin” or tolerance the memory cell has before failing under stressed conditions. The memory margin test may systematically vary operational parameters, such as supply voltage (testing both above and below the nominal range), timing parameters (making access times tighter or clock frequencies higher than specified), and sometimes operating temperature (pushing towards the high or low extremes). While applying these stressful conditions, functional tests involving various data patterns are run to detect errors. Identifying the point at which failures occur may allow the control circuit to quantify the operating margin, ensuring the memory cell is not just functional but also resilient to variations that might occur within the device.

In some examples, the control circuit may test a subset of the memory cells in the device. The control circuit may test a subset of the memory cells where some memory cells have been identified for more frequent tests, as described below with reference to block 353 of FIG. 3. In some examples, the control circuit may test a subset of the memory cells where the control circuit does not have time to test every memory cell in the device. For example, a test of every memory cell in the device may take approximately three hours. If, at block 210, the control circuit determines that the device may be idle for approximately two hours, the control circuit may test a subset of the memory cells such that the test of the subset of the memory cells takes less than two hours.

At block 240, the control circuit may calculate a health score for the memory cell based on the test. The health score may be based on the margin resulting from the memory margin test performed at block 230. The health score may be a “pass” where the memory cell passes the memory margin test with a high margin. The health score may be an “marginal” where the memory cell passes the memory margin test with an adequate margin, but where the margin is low enough that the control circuit may determine that the memory cell may be monitored more frequently. The health score may be a “fail” where the memory cell has a poor margin.

At block 250, the control circuit may diagnose the memory cell based on the health score. For example, if the control circuit assigns a passing score to the memory cell, the control circuit may diagnose that the memory cell is operational. If the control circuit assigns a marginal score to the memory cell, the control circuit may diagnose that the memory cell is operating but may be nearing a failure. If the control circuit assigns a failing score to the memory cell, the control circuit may diagnose that the memory cell is no longer operational or has failed.

At block 260, the control circuit may determine if there is another memory cell to test. If there is another memory cell to test, method 200 may return to block 210 to schedule and test the next memory cell. Otherwise method 200 may be complete.

Although FIG. 2 discloses a particular number of operations related to method 200, method 200 may be executed with greater or fewer operations than those depicted in FIG. 2. In addition, although FIG. 2 discloses a certain order of operations to be taken with respect to method 200, the operations comprising method 200 may be completed in any suitable order.

FIG. 3 illustrates a more detailed method for predicting when a memory cell is idle and scheduling testing of the memory cell during an idle period, according to examples of the present disclosure. Method 300 may be implemented using a control circuit such as control circuit 110 shown in FIG. 1 communicatively coupled to a memory cell, such as memory cell 120 shown in FIG. 1, designed to perform the functions disclosed herein, in combination with a processor, or any other system operable to implement method 300. Although examples have been described above, other variations and examples may be made from this disclosure without departing from the spirit and scope of these disclosed examples.

Method 300 may begin at block 310 where the control circuit may identify a predicted time when the memory cell may be idle. The memory cell may be incorporated into a device, such as but not limited to, devices in the automotive, industrial, robotic, or drone industries. The device may operate at some times and may have periods of time when the device is idle. For example, an automobile may be active while a driver is commuting to and from work, but may be idle while the driver is at work and while the driver is at home. The control circuit may periodically check the device to determine if it is idle or in operation. The control circuit may check the device on any suitable basis. For example, the control circuit may check the device on a schedule programmed in the control circuit or the operator of the device may specify how often the control circuit is to perform the check.

At block 312, the control circuit may learn an operational schedule of the memory cell. Continuing the example of the device being an automobile, the control circuit may learn that the automobile is idle from 9:00 a.m. to 5:00 p.m. when the driver is at work and from 6:00 p.m. to 8:00 a.m. when the driver is at home. In some examples, the control circuit may use machine learning to identify when the device is idle. The control circuit may also have access to the calendar of an operator (e.g., driver) of the device to identify whether the device may be operational at times outside of the typical operational schedule of the device. For example, the control circuit may access the operator's calendar to determine that the driver has an appointment and the automobile may be in operation during the workday. The control circuit may also be aware of holidays, weekends versus weekdays, and other events that may alter the typical operational schedule of the device.

At block 320, the control circuit may schedule a test of the memory cell at a schedule time during the predicted time. For example, where the control circuit determines that the device is idle from 9:00 a.m. to 5:00 p.m. and from 6:00 p.m. to 8:00 a.m., the control circuit may schedule the test of the memory cell during that time. In some examples, the operator of the device may schedule the test. For example, the operator of the device may instruct the control circuit that the device is idle and control circuit may proceed to block 230 to test the memory cell. In other example, the control circuit may prompt the operator to confirm that the device is idle and that the control circuit may proceed to block 330.

At block 330, the control circuit may perform the test of the memory cell at the scheduled time. The test may be any suitable test, such as a memory margin test. A memory margin test may assess the robustness and reliability of the NVM and may determine how much “margin” or tolerance the memory cell has before failing under stressed conditions. The memory margin test may systematically vary operational parameters, such as supply voltage (testing both above and below the nominal range), timing parameters (making access times tighter or clock frequencies higher than specified), and sometimes operating temperature (pushing towards the high or low extremes). While applying these stressful conditions, functional tests involving various data patterns are run to detect errors. Identifying the point at which failures occur may allow the control circuit to quantify the operating margin, ensuring the memory cell is not just functional but also resilient to variations that might occur within the device.

At block 332, the control circuit may compare a content of the memory cell to a content of a second memory. For example, the control circuit may read a memory cell of the NVM, compare the content of the memory cell to a copy of the content of the memory cell stored on a second memory elsewhere in the device (e.g., in multimedia card (MMC) or solid state drive (SSD)). For example, in a device with 3,200 control circuits of 256 kilobytes (KB) of memory associated with a given control circuit, the second memory may have a size of 0.82 gigabytes (GB) to fully backup the NVM associated with other control circuits in the device.

In some examples, the control circuit may test a subset of the memory cells in the device. The control circuit may test a subset of the memory cells where some memory cells have been identified for more frequent tests, as described below with reference to block 353. In some examples, the control circuit may test a subset of the memory cells where the control circuit does not have time to test all memory cells in the device. For example, a test of all memory cells in the device may take approximately three hours. If, at block 210, the control circuit determines that the device may be idle for approximately two hours, the control circuit may test a subset of the memory cells such that the test of the subset of the memory cells takes less than two hours.

At block 340, the control circuit may calculate a health score for the memory cell based on the test. The health score may be based on the margin resulting from the memory margin test performed at block 330. The health score may be a “pass” where the memory cell passes the memory margin test with a high margin. The health score may be an “marginal” where the memory cell passes the memory margin test with an adequate margin, but where the margin is low enough that the control circuit may determine that the memory cell may be monitored more frequently. The health score may be a “fail” where the memory cell has a poor margin.

At block 350, the control circuit may diagnose the memory cell based on the health score. For example, if the control circuit assigns a passing score to the memory cell, the control circuit may diagnose that the memory cell is operational. If the control circuit assigns a marginal score to the memory cell, the control circuit may diagnose that the memory cell is operating but may be nearing a failure. If the control circuit assigns a failing score to the memory cell, the control circuit may diagnose that the memory cell is no longer operational or has failed.

At block 351, the control circuit may determine whether the health score for the memory cell is passing. Where the health score is passing, method 300 may proceed to block 360.

At block 352, the control circuit may determine whether the health score for the memory cell is marginal. Where the health score is marginal, method 300 may proceed to block 353. At block 353, the control circuit may increase the testing frequency of the memory cell. The marginal health score may indicate that the memory cell is not performing as robustly as expected and the control circuit may monitor the memory cell more closely.

At block 354, the control circuit may determine whether the health score for the memory cell is failed. Where the health score is failed, method 300 may proceed to block 355, 356, 357, or any combination thereof.

At block 355, the control circuit may rewrite the memory cell. For example, the control circuit may erase and rewrite data to the memory cell. In other examples, the control circuit may use error correction code (ECC) mechanisms to detecting and correcting errors. The ECC mechanism may include adding redundant bits, often called parity or check bits, to the original data block using mathematical algorithms (e.g., Hamming codes, Reed-Solomon codes, low-density parity-check (LDPC) codes, or Bose-Chaudhuri-Hocquenghem (BCH) codes). When the data is stored or transmitted, the extra bits may be calculated and appended. Upon retrieval or reception, the ECC mechanism may recalculate the check bits based on the received data and compares them with the originally appended check bits. A mismatch may indicate that an error has occurred. The control circuit may use the pattern of the mismatch, referred to as the error syndrome, to pinpoint the exact memory cell that is incorrect and flip it back to its correct state, to maintain data accuracy without needing re-transmission or signaling a failure for minor, correctable faults.

At block 356, the control circuit may trigger a failure alert indicating the memory cell has failed. For example, the control circuit may alert an operator of the device that the memory cell has failed and is to be scheduled for a replacement.

At block 357, the control circuit may flag the memory cell as unusable. By flagging the memory cell as unusable, the memory cell may be avoided for future use.

At block 360, the control circuit may determine if there is another memory cell to test. If there is another memory cell to test, method 300 may return to block 310 to schedule and test the next memory cell. Otherwise method 300 may be complete.

Although FIG. 3 discloses a particular number of operations related to method 300, method 300 may be executed with greater or fewer operations than those depicted in FIG. 3. In addition, although FIG. 3 discloses a certain order of operations to be taken with respect to method 300, the operations comprising method 300 may be completed in any suitable order.

Although examples have been described above, other variations and examples may be made from this disclosure without departing from the spirit and scope of these disclosed examples.

1. An apparatus, comprising:
a memory cell interface communicatively coupled to a memory cell; and
a control circuit communicatively coupled to the memory cell interface, the control circuit to:
identify a predicted time when the memory cell is idle;
schedule a test of the memory cell at a schedule time during the predicted time;
perform the test of the memory cell at the scheduled time;
calculate a health score for the memory cell based on the test; and
diagnose the memory cell based on the health score.

2. The apparatus of claim 1, wherein the control circuit is to:
determine that the health score for the memory cell is marginal; and
increase a testing frequency of the memory cell.

3. The apparatus of claim 1, wherein the control circuit is to:
determine that the health score for the memory cell is failed; and
rewrite the memory cell.

4. The apparatus of claim 1, wherein the control circuit is to:
determine that the health score for the memory cell is failed; and
trigger a failure alert indicating the memory cell has failed.

5. The apparatus of claim 1, wherein the control circuit is to:
determine that the health score for the memory cell is failed; and
flag the memory cell as unusable.

6. The apparatus of claim 1, wherein determining whether the memory cell is idle includes learning an operational schedule of the memory cell.

7. The apparatus of claim 1, comprising:
a second memory interface communicatively coupled to a second memory and the control circuit; and
wherein testing the memory cell includes comparing a content of the memory cell to a content of the second memory.

8. A method, comprising:
identifying a predicted time when a memory cell is idle;
scheduling a test of the memory cell at a schedule time during the predicted time;
performing the test of the memory cell at the scheduled time;
calculating a health score for the memory cell based on the test; and
diagnosing the memory cell based on the health score.

9. The method of claim 8, comprising:
determining that the health score for the memory cell is marginal; and
increasing a testing frequency of the memory cell.

10. The method of claim 8, comprising:
determining that the health score for the memory cell is failed; and
rewriting the memory cell.

11. The method of claim 8, comprising:
determining that the health score for the memory cell is failed; and
triggering a failure alert indicating the memory cell has failed.

12. The method of claim 8, comprising:
determining that the health score for the memory cell is failed; and
flagging the memory cell as unusable.

13. The method of claim 8, wherein determining whether the memory cell is idle includes learning an operational schedule of the memory cell.

14. The method of claim 8, wherein testing the memory cell includes comparing a content of the memory cell to a content of a second memory.

15. A system, comprising:
a memory cell; and
a control circuit communicatively coupled to the memory cell, the control circuit to:
identify a predicted time when the memory cell is idle;
schedule a test of the memory cell at a schedule time during the predicted time;
perform the test of the memory cell at the scheduled time;
calculate a health score for the memory cell based on the test; and
diagnose the memory cell based on the health score.

16. The system of claim 15, wherein the control circuit is to:
determine that the health score for the memory cell is marginal; and
increase a testing frequency of the memory cell.

17. The system of claim 15, wherein the control circuit is to:
determine that the health score for the memory cell is failed; and
rewrite the memory cell.

18. The system of claim 15, wherein the control circuit is to:
determine that the health score for the memory cell is failed; and
trigger a failure alert indicating the memory cell has failed.

19. The system of claim 15, wherein the control circuit is to:
determine that the health score for the memory cell is failed; and
flag the memory cell as unusable.

20. The system of claim 15, wherein determining whether the memory cell is idle includes learning an operational schedule of the memory cell.
